(19) United States
(12) Patent Application Publication
(10) Pub. No.: US 2006/0138473 A1
(43) Pub. Date: Jun. 29, 2006

(54) Semiconductor device and manufacturing method thereof

(75) Inventors: Tsuyoshi Kawagoe, Tokyo (JP); Isamu Asano, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY INC.

(21) Appl. No.: 11/313,742

(22) Filed: Dec. 22, 2005

(30) Foreign Application Priority Data
Dec. 24, 2004 (JP) 2004-373236

(51) Int. Cl. H01L 29/768

(52) U.S. Cl. 257/246

(57) ABSTRACT

A semiconductor device having a plurality of phase change devices rewritably storing data, comprising: an insulating film deposited on a semiconductor substrate using an insulating material having sufficient adhesion to a chalcogenide-based phase change material; a chalcogenide film formed by embedding the chalcogenide-based phase change material in a hole formed at each of bit areas separated from each other in the insulating film; and an electrode structure for supplying a current to each the phase change device made of the chalcogenide film in the bit area.

### BACKGROUND OF THE INVENTION

1. Field of the Invention

The present invention relates to a semiconductor device using chalcogenide-based phase change material as a memory device and a method of manufacturing the semiconductor device.

2. Related Art

In regards to non-volatile memory widely used as data storage means of portable devices or the like, attention is paid to phase change memory using structural changes of phase change material as a next-generation technology. The phase change memory has a structure in which a memory device is formed on a semiconductor substrate using a chalcogenide-based phase change material such as germanium, antimony and tellurium, and is heated. Such a structure causes the phase change material to transition freely between its high-resistance amorphous state and low-resistance crystalline state and enables to rewritably store data (for example, see U.S. Pat. No. 6,590,807 B2 and U.S. Pat. No. 6,567,296B1).

FIG. 15A shows a schematic cross-sectional structure of a phase change memory such that the above-mentioned memory device using the phase change material is formed on a semiconductor substrate. MOS transistors (not shown) are formed on a semiconductor substrate 200, and a chalcogenide film 202 is formed on the substrate via a silicon oxide film 201 as an insulating film. Plugs 203 are formed through the silicon oxide film 201 tobe a lower electrode structure to connect the chalcogenide film 202 to the MOS transistor for each bit. An upper electrode 204 is formed on the chalcogenide film 202 to supply current. By such a structure, it is possible to build the non-volatile phase change memory capable of reading and writing data in the chalcogenide film 202.

However, in the cross-sectional structure as shown in FIG. 15A, it is known that adhesion is generally poor between the chalcogenide film 202 and the silicon oxide film 201. Therefore, as shown in FIG.15B, the chalcogenide film 202 can be delaminated from the silicon oxide film 201 at the interface therebetween in the manufacturing process of the phase change memory. In order to prevent such delamination, there is amethod in which an adhesive layer such as titanium is inserted between the chalcogenide film 202 and the silicon oxide film 201. However, in this method, elements contained in the adhesive layer diffuse into the chalcogenide film 202, and thereby the composition of the chalcogenide film 202 changes and causes deterioration in characteristics.

Further, in the cross-sectional structure as shown in FIG. 15A, it is a problem that disturbance occurs between bit areas connected to the plugs 203 adjacent and spaced a distance d to/from each other when the structural changes occur in the chalcogenide film 202 by currents flowing via the plugs 203 in writing operation of desired data. In other words, when the distance between adjacent bit areas is small in the chalcogenide film 202, there is a possibility that data of the adjacent bit area is rewritten or the data is corrupted due to an adverse effect such that heat of one bit area is conducted to the other bit area. Meanwhile, in an arrangement that the distance between bit areas is large in the chalcogenide film 202 to suppress disturbance, it is a problem that the chip area increases and the cost is thereby increased.

### SUMMARY OF THE INVENTION

It is an object of the present invention to provide a semiconductor device with high reliability and low cost which effectively prevents delamination of a chalcogenide film in a manufacturing process, suppresses an effect of disturbance between chalcogenide films at positions of adjacent bit areas to hold data reliably, and densely disposes phase change devices not to increase chip area, when the semiconductor device is configured using a chalcogenide-based phase change material.

An aspect of the present invention is a semiconductor device having a plurality of phase change devices rewritably storing data, comprising: an insulating film deposited on a semiconductor substrate using an insulating material having sufficient adhesion to a chalcogenide-based phase change material; a chalcogenide film formed by embedding said chalcogenide-based phase change material in a hole formed at each of bit areas separated from each other in said insulating film; and an electrode structure for supplying a current to each said phase change device made of said chalcogenide film in said bit area.

According to the aspect of the present invention, since the chalcogenide film is brought into contact with the insulating film with sufficient adhesion on the semiconductor substrate and is embedded in the insulating film to be divided into bit areas, each chalcogenide film is thus small and brought into contact with the insulating film at its side. Therefore, such a structure is obtained that prevents stress to peel off the chalcogenide film, and it is possible to reliably prevent delamination of the chalcogenide film from the insulating film. Further, when a heater heats and the temperature of the chalcogenide is increased due to the current supplied via the electrode structure in writing operation of the phase change device, since each chalcogenide film is separated, it is possible to suppress disturbance on the adjacent bit area. Furthermore, the volume of each chalcogenide film is so small that it is possible to reduce fluctuations in characteristics and increase the heating efficiency.

In the semiconductor device, a silicon nitride film may be used as said insulating film.

In the semiconductor device, said chalcogenide-based phase change material may contain germanium, antimony and tellurium.

In the semiconductor device, said chalcogenide film having a predetermined thickness smaller than the thickness of said insulating film may be embedded in the hole formed in said insulating film, and a conductive film to be said electrode structure may be formed thereon.

An aspect of the present invention is a semiconductor device having a plurality of phase change devices rewritably storing data, comprising: an insulating film deposited on a semiconductor substrate; a silicon nitride film formed on the sidewall surface of a hole formed at each of bit areas separated from each other in said insulating film; and a chalcogenide film formed by embedding chalcogenide-based phase change material inside said silicon nitride film in the hole; and an electrode structure for supplying a current to each said phase change device made of said chalcogenide film in said bit area.

On the other hand, an aspect of the present invention is a method of manufacturing a semiconductor device having a plurality of phase change devices rewritably storing data, comprising the steps of: depositing an insulating film on a semiconductor substrate using a silicon nitride film; forming a chalcogenide film by forming a hole at each of bit areas separated from each other in said insulating film and by embedding a chalcogenide-based phase change material in the hole; and forming an electrode structure for supplying a current to each said phase change device made of said chalcogenide film in said bit areas.

In the method, said chalcogenide film with a predetermined thickness smaller than the thickness of said insulating film may be embedded in the hole formed in said insulating film in the step in which said chalcogenide film is formed, and a conductive film to be said electrode structure may be formed on said chalcogenide film in the hole in the step in which said electrode structure is formed.

An aspect of the present invention is a method of manufacturing a semiconductor device having a plurality of phase change devices rewritably storing data, comprising the steps of: depositing an insulating film on a semiconductor substrate using a silicon oxide film; forming a hole at each of bit areas separated from each other in said insulating film and forming a silicon nitride film on the sidewall surface of the hole; forming a chalcogenide film by embedding a chalcogenide-based phase change material inside said silicon nitride film in the hol; and forming an electrode structure for supplying a current to each said phase change device made of said chalcogenide film in said bit area.

As described above, according to the present invention, such an insulating film is provided on a semiconductor substrate that has sufficient adhesion to a chalcogenide-based phase change material, a chalcogenide film is embedded in holes formed in the insulating film, and it is thereby possible to effectively prevent delamination of the chalcogenide film in the manufacturing process. Further, it is possible to suppress the effect of disturbance between chalcogenide films at positions of adjacent bit areas and to realize a structure in which phase change devices are densely arranged so that chip area is reduced. Accordingly, the present invention enables implementation of a semiconductor device with low cost and high reliability in its manufacturing.

### BRIEF DESCRIPTION OF THE DRAWINGS

The above and other objects and features of the invention will appear more fully hereinafter from a consideration of the following description taken in connection with the accompanying drawing wherein one example is illustrated by way of example, in which;

FIG.1 is a view showing a schematic cross-sectional structure of phase change memory of an embodiment of the invention;

FIG. 2 is a view showing a step of forming an impurity diffusion region 11 and a device isolation region 12 on a semiconductor substrate 10 in a manufacturing method of the phase change memory of the embodiment;

FIG. 3 is a view showing a step of forming a structure of MOS transistors for use in circuits constituting the entire phase change memory in the manufacturing method of the phase change memory of the embodiment;

FIG. 4 is a view showing a step of forming a sidewall 18 of a silicon nitride film in a gate electrode in the manufacturing method of the phase change memory of the embodiment;

FIG. 5 is a view showing a step of forming an insulating film 19 between adjacent gate electrodes in the manufacturing method of the phase change memory of the embodiment;

FIG. 6 is a view showing a step of embedding conductive films in contact holes to form first contact plugs 20 in the manufacturing method of the phase change memory of the embodiment;

FIG. 7 is a view showing a step of depositing a conductive film 21 and further depositing an inter-layer insulating film 22 thereon in the manufacturing method of the phase change memory of the embodiment;

FIG. 8 is a view showing a step of embedding conductive films in contact holes to form second contact plugs 23 in the manufacturing method of the phase change memory of the embodiment;

FIG. 9 is a view showing a step of embedding conductive films in contact holes to form third contact plugs 24 in the manufacturing method of the phase change memory of the embodiment;

FIG. 10 is a view showing a step of depositing a silicon nitride film 25 over an inter-layer insulting film 22 and opening holes therein in the manufacturing method of the phase change memory of the embodiment;

FIG. 11 is a view showing a step of embedding chalcogenide films 26 in the holes opened in a silicon nitride film 25 in the manufacturing method of the phase change memory of the embodiment;

FIG. 12 is a view showing a step of forming an upper electrode 27 in the manufacturing method of the phase change memory of the embodiment;

FIG. 13 is a view showing a first modification of the semiconductor device of the embodiment;

FIG. 14 is a view showing a second modification of the semiconductor device of the embodiment; and

FIGS. 15A and 15B are views showing a schematic cross-sectional structure of conventional phase change memory.

### DETAILED DESCRIPTION OF THE INVENTION

An embodiment of the present invention will specifically be described below with reference to accompanying drawings. This embodiment describes non-volatile phase change memory using chalcogenide-based phase change material as an example of a semiconductor device to which the invention is applied.

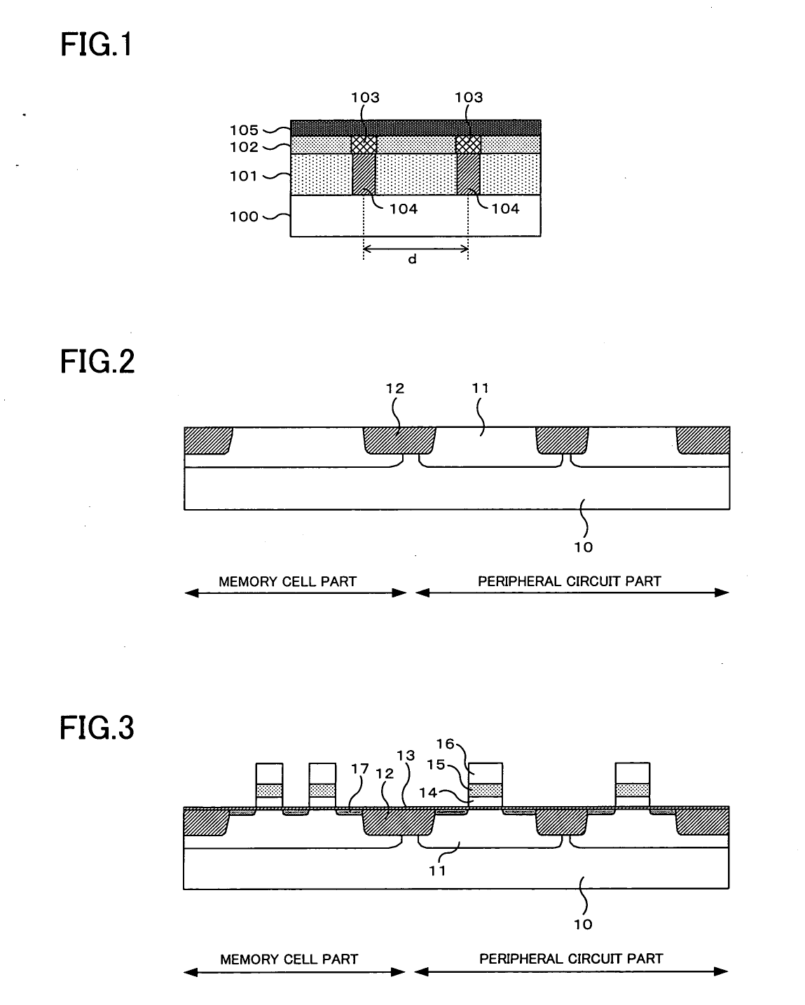

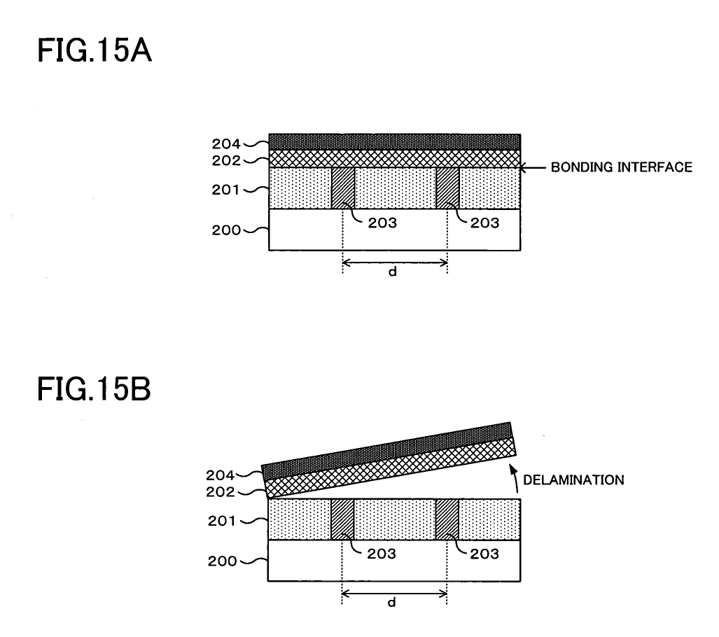

A basic structure of the phase change memory of this embodiment will be described below. FIG. 1 is a view showing a schematic cross-sectional structure of the phase change memory of this embodiment, and corresponds to FIG. 15A showing a conventional structure. In FIG. 1, MOS transistors (not shown) are formed on a semiconductor substrate 100, and a silicon oxide film 101 is formed on the substrate as an insulating film. A silicon nitride film 102 is formed on the silicon oxide film 101. In the silicon nitride film 102, holes are respectively formed at a plurality of bit areas spaced a distance d from each other, and a chalcogenide film 103 is embedded in each bit area. The chalcogenide film 103 contains germanium (Ge), antimony (Sb) and tellurium (Te), for example.

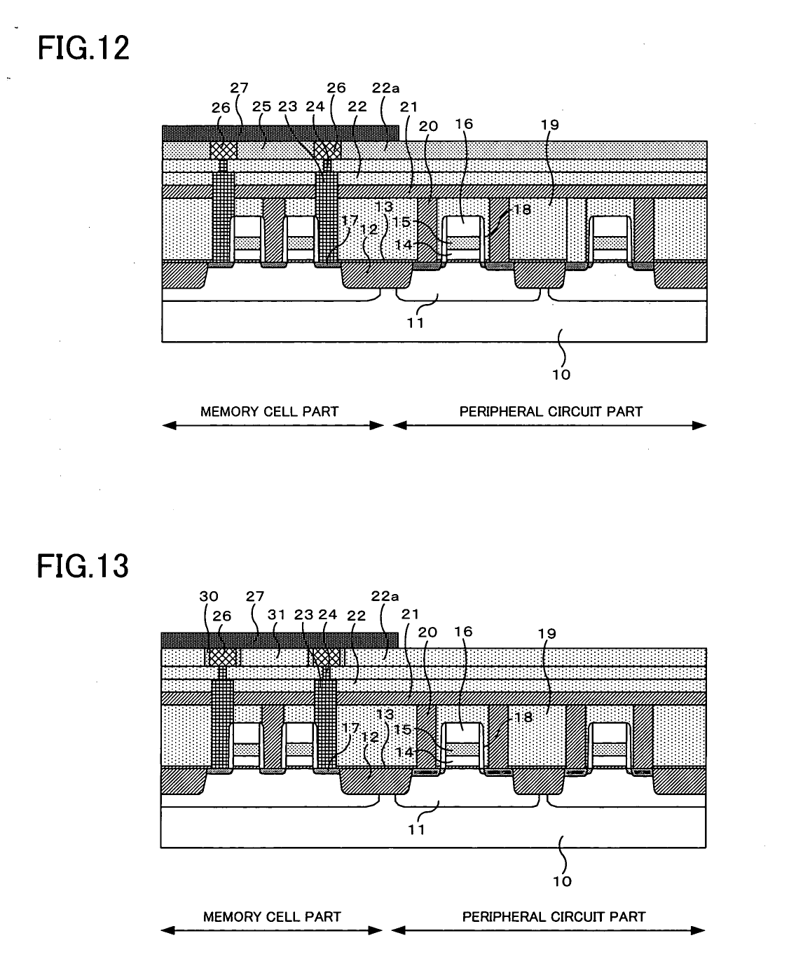

In the silicon oxide film 101, apluralityof plugs 104 spaced the distance d from each other are formed at positions corresponding to respective chalcogenide films 103 as a lower electrode structure to connect to the MOS transistor for each bit area. An upper electrode 105 for supplying current to the chalcogenide films 103 is formed on the silicon nitride film 102 and the chalcogenide films 103. In addition, regarding the phase change memory of this embodiment, a more specific cross-sectional structural view will be described later (FIG. 12).

Comparing the cross-sectional structure as shown in FIG. 1 with FIG. 15A, there is a difference in the structure of the silicon nitride film 102 and the chalcogenide film 103. In other words, the chalcogenide film 103 generally has poor adhesion to a silicon oxide film, while maintaining sufficient adhesion to the silicon nitride film 102. In the case of FIG. 15A, the chalcogenide film 202 is in contact with the silicon oxide film 201 with a large interface, resulting in a structure in which strong stress is applied during delamination. In contrast thereto, in the case of this embodiment, since sides of the chalcogenide film 103 is in contact with the silicon nitride film 102 for each bit area, the volume and the surface area are small, and only small stress is applied in the lateral direction, thus resulting in a structure for preventing delamination. Further, in the cross-sectional structure as shown in FIG. 1, each chalcogenide film 103 has a stable structure supported at its lower side by the plug 104.

Moreover, while in the case of FIG. 15A, a structure is provided, in which disturbance occurs between adjacent bit areas in writing operation of desired data in the chalcogenide film 202, in the case of this embodiment, a structure capable of suppressing such disturbance is provided. In other words, when a current is supplied to the plug 104 connected to the chalcogenide film 103 for one bit area so that the interface between the chalcogenide film 103 and the plug 104 is heated and thereby increasing the temperature of the chalcogenide film 103 to cause a phase change by heat conduction, the heat is diffused from the chalcogenide film 103 via the upper electrode 105 having a large size. That is, such a structure is provided that the heat is hardly conducted between the adjacent chalcogenide films 103 in respective bit areas spaced the distance d from each other. Therefore, it is possible in this embodiment to avoid instability due to disturbance and effectively prevent data corruption and the like in writing operation in an arbitrary bit area.

A method of manufacturing the phase change memory of this embodiment is described below. First, as shown in FIG. 2, impurity diffusion regions 11 and device isolation regions 12 are formed in predetermined regions on a semiconductor substrate 10 made of silicon single crystal. The device isolation region 12 is formed by filling a shallow trench formed in the semiconductor substrate 11 with a silicon oxide film. The impurity diffusion region 11 is formed by ion implantation in which impurity ions are injected into a predetermined area isolated by the device isolation region 12. In addition, the area of the semiconductor substrate 10 is divided into a memory cell part and a peripheral circuit part as shown in FIG. 2.

Next, as shown in FIG. 3, a structure of MOS transistors for use in circuits in the entire phase change memory is formed. In other words, an insulating film 13 is formed on the impurity diffusion region 11, a polycrystalline silicon film 14 and a tungsten film are deposited on the insulating film 13 to be a gate electrode, and a silicon nitride film 16 is further deposited on the tungsten film 15 to be a hard mask. At this time, not only MOS transistors used in memory cells including the phase change devices but also other MOS transistors for use in the other circuit part are also formed. Thereafter, the gate electrodes of the MOS transistors are formed by performing photolithography and dry etching. Then, diffusion layers 17 corresponding to source and drain are formed by ion implantation in which desired impurity are injected into channel regions of the MOS transistors.

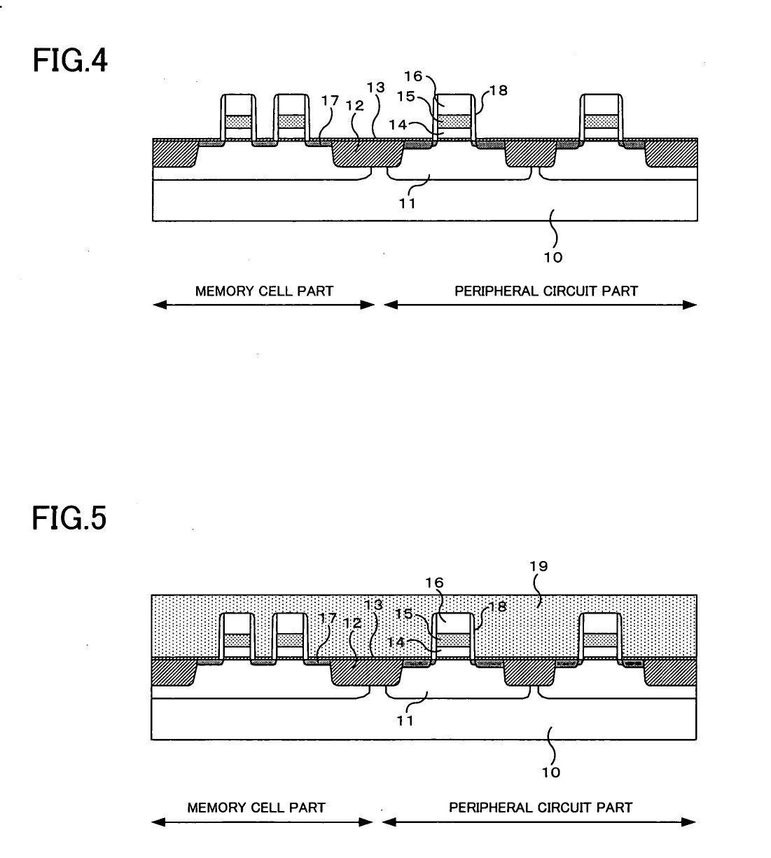

Next, as shown in FIG. 4, after a silicon nitride film (not shown) is deposited in specified thickness on the entire semiconductor substrate 10, a sidewall 18 of the silicon nitride film is formed on the gate electrode by etching back. Thereafter, in the memory cell part, the density of impurity is increased by another ion implantation in which desired impurity are injected into only the peripheral circuit part using a mask of photoresist (not shown), and a structure of the diffusion layers 17 corresponding to the source and drain is thus completed.

Next, as shown in FIG. 5, an insulating film 19 made of silicon oxide film, for example, is formed in predetermined film thickness between adjacent gate electrodes, and the surface thereof is flattened by polishing using CMP (Chemical Mechanical Polishing), for example. The insulating film 19 can be formed using CVD (Chemical Vapor Deposition), for example.

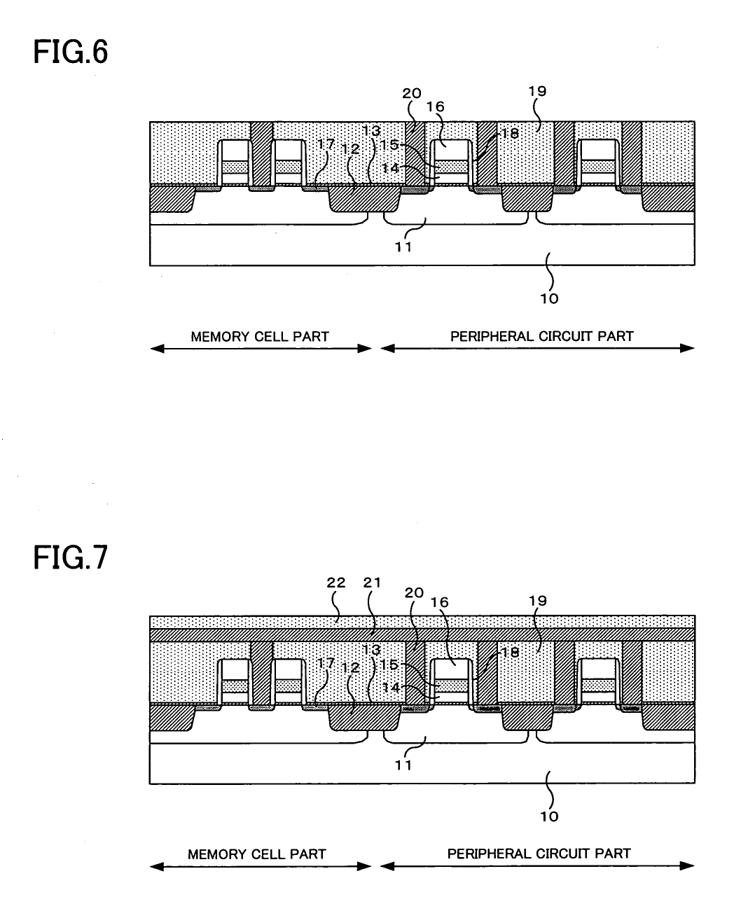

Next, as shown in FIG. 6, contact holes connected to bit lines of the phase change memory and local wirings of the peripheral circuit part are opened by photolithography and dry etching, and conductive films made of, for example, tungsten is embedded in the contact holes. Then, by polishing excessive portion of the conductive films by CMP, for example, first contact plugs 20 are formed.

Next, as shown in FIG. 7, a conductive film 21 is further deposited over the semiconductor substrate 10, and photolithography and dry etching is performed. Then, in the conductive film 21, the bit lines of the phase change memory and the local wirings of the peripheral circuit part are formed, and the local wirings are connected to the first contact plugs 20. In a state in which such wirings are formed, an inter-layer insulating film 22 made of a silicon oxide film is deposited over the semiconductor substrate 10. In this case, to improve the flatness of the inter-layer insulating film 22, it is preferable to polish the inter-layer insulating film 22 by CMP, for example.

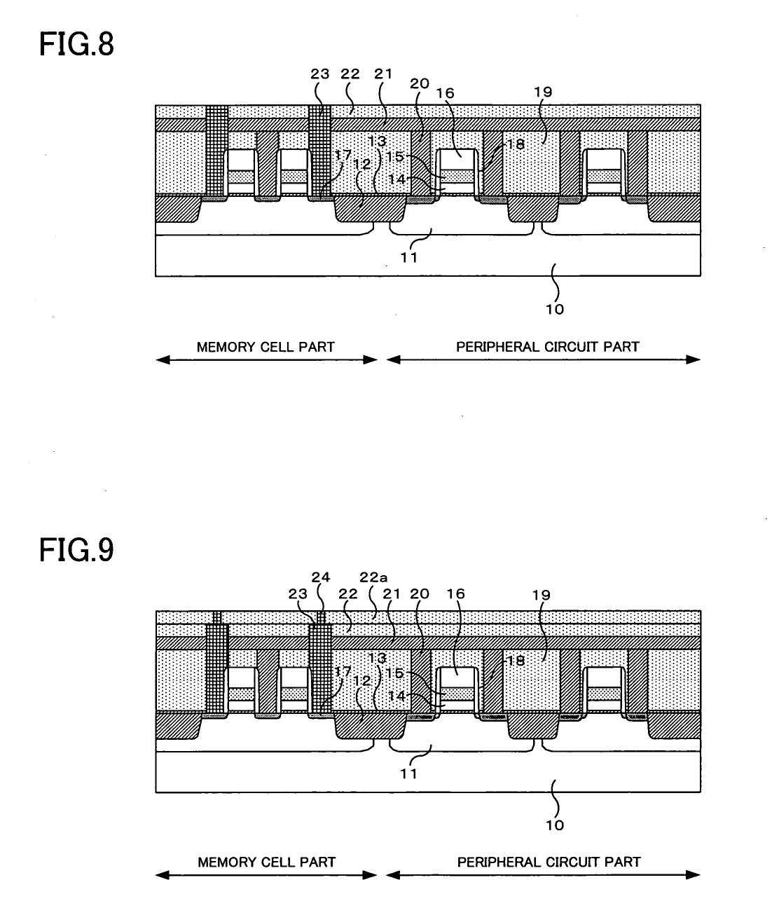

Next, as shown in FIG. 8, contact holes for electrical connection with the phase change devices are opened by photolithography and dry etching, and conductive films are embedded in the contact holes. Then, by polishing excessive portions of the conductive films, for example, by CMP, second contact plugs 23 are formed. As the conductive film of the second contact plug 23, for example, polycrystalline silicon doped with impurity is used.

Next, as shown in FIG. 9, an inter-layer insulating film 22a is further deposited on the inter-layer insulating film 22, and contact holes for electrical connection with the phase change devices are opened by photolithography and dry etching. In the contact holes, for example, films of titanium and titanium nitride are formed to prevent silicide formation and reaction, and a film of tungsten is formed as a conductive film. Then, bypolishing excessive portion of the films using CMP, for example, third contact plugs 24 are formed. Each third contact plug 24 is integrally connected to the second contact plug 23, thereby constituting a lower electrode structure, and has functions of a current source to the phase change devices and a heater.

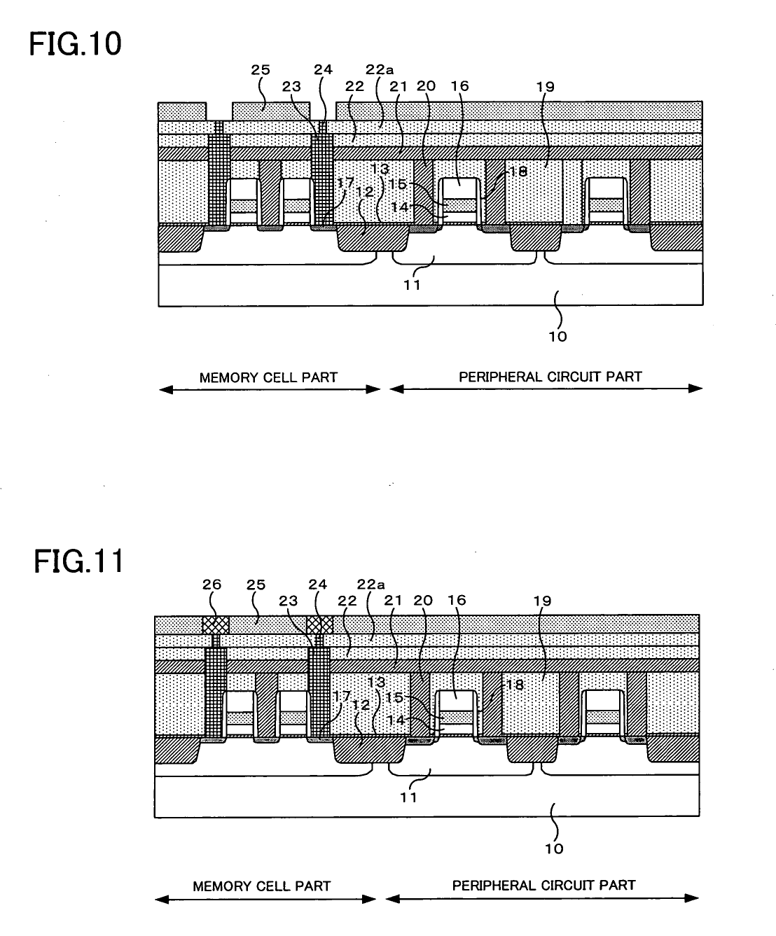

Next, as shown in FIG. 10, a silicon nitride film 25 is deposited on the inter-layer insulating film 22a. Then, by photolithography and dry etching, holes to be filled with the phase change material are opened at respective positions corresponding to the second contact plugs 23 and the third contact plugs 24.

Next, as shown in FIG. 11, chalcogenide films 26 as the phase change material are embedded in the holes opened in the silicon nitride film 25 as shown in FIG. 10. The excessive portions of the film are polished and removed using CMP, for example. Thus, a basic structure of the phase change device comprising the chalcogenide film 26 is formed.

Next, as shown in FIG. 12, an upper electrode 27 is formed by depositing, for example, tungsten. Then, by photolithography and dry etching, the upper electrode 27 is processed into a desired pattern corresponding to the placement of the chalcogenide film 26. A wiring structure for supplying current to the phase change device is formed around the upper electrode 27.

Through the manufacturing steps as shown in FIGS .2 to 12, the phase change memory is completed as the semiconductor device of this_embodiment. The phase change memory has the same operation and effect as in the basic structure as shown in FIG. 1, reliably prevents delamination of the chalcogenide film 26, and sufficiently suppresses disturbance between adjacent bit areas. In addition, details of the structure and the manufacturing method of the semiconductor device of this embodiment are not limited to examples as shown in FIGS. 2 to 12, and various structures and manufacturing methods can be applied. Two modifications corresponding to the structure as shown in FIG. 12 will be described below with respect to the structure of the semiconductor device of this embodiment.

FIG. 13 is a view showing a first modification of the semiconductor device of this embodiment. The structure of the silicon nitride film 25 as shown in FIG. 12 differs in the first modification. That is, as shown in FIG. 13, an inter-layer insulating film 31 made of a silicon oxide film is formed in the layer where the chalcogenide films 26 are formed. A silicon nitride film 30 is formed on the sidewall surface of the hole to be filled with each chalcogenide film 26 in the inter-layer insulating film 31, and the chalcogenide film 26 is embedded inside the silicon nitride film 30. In addition, the other structural elements in FIG. 13 are the same as in FIG. 12 and descriptions thereof are omitted.

Thus, according to the structure of the first modification, the area occupied by the silicon nitride films 30 in the chip area is greatly reduced as compared with the structure as shown in FIG. 12, while sufficient adhesion is maintained between the silicon nitride film 30 and the chalcogenide film 26. Accordingly, it is possible to reduce parasitic capacitance between wirings of the silicon nitride films 30 while preventing delamination of the chalcogenide film 26, and to improve the characteristics.

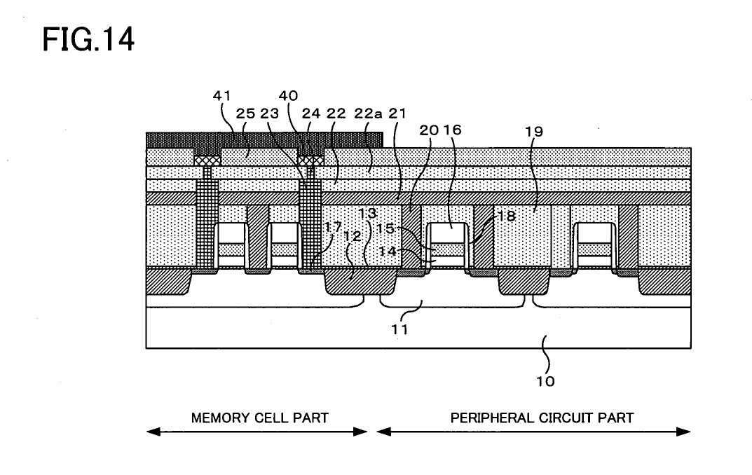

Next, FIG. 14 shows a second modification of the semiconductor device of this embodiment. The structure of the chalcogenide film 26 and the upper electrode 27 as shown in FIG. 12 differs in the second modification. That is, as shown in FIG. 14, chalcogenide films 40 with a predetermined thickness smaller than the thickness of the silicon nitride film 25 are embedded in the holes in the silicon nitride film 25. An upper electrode 41 with downward convex shape is consecutively formed in an upper part of the holes in the silicon nitride film 25 in contact with the chalcogenide films 40. In addition, the other structural elements in FIG. 14 are the same as in FIG. 12 and descriptions thereof are omitted.

Thus, according to the structure of the second modification, as well as the chalcogenide film 40 and the silicon nitride film 25, an excellent interface is maintained between the chalcogenide film 40 and the upper electrode 41, thereby enabling a structure to prevent delamination. Further, byreducing the volume of the chalcogenide film 26 corresponding to each bit area, it is possible to further enhance the heating efficiency in writing.

Although the present invention has been specifically described based on the embodiment, the present invention is not limited to the above-described embodiment, and various variations and modifications may be made without departing from the scope of the present invention. For example, the case is described where the semiconductor device of this embodiment is applied to the non-volatile phase change memory, but the present invention is widely applicable to semiconductor devices having the chalcogenide film 103 and the silicon nitride film 102 in the structure as shown in FIG. 1. In this case, the silicon nitride film 102 can be replaced by other insulating material shaving sufficient adhesion to the chalcogenide film 103. Further, the chalcogenide film 103 may contain materials other than germanium, antimony and tellurium. Furthermore, the electrode structure and the MOS transistor structure in the semiconductor device are not limited to this embodiment, and various forms can be applied.

The present invention is not limited to the above described embodiments, and various variations and modifications may be possible without departing from the scope of the present invention.

This application is based on the Japanese Patent application No. 2004-373236 filed on Dec. 24, 2004, entire content of which is expressly incorporated by reference herein.

1. A semiconductor device having a plurality of phase change devices rewritably storing data, comprising:
an insulating film deposited on a semiconductor substrate using an insulating material having sufficient adhesion to a chalcogenide-based phase change material;
a chalcogenide film formed by embedding said chalcogenide-based phase change material in a hole formed at each of bit areas separated from each other in said insulating film; and
an electrode structure for supplying a current to each said phase change device made of said chalcogenide film in said bit area.

2. A semiconductor device according to claim 1, wherein a silicon nitride film is used as said insulating film.

3. A semiconductor device according to claim 1, wherein said chalcogenide-based phase change material contains germanium, antimony and tellurium.

4. A semiconductor device according to claim 1, wherein said chalcogenide film having a predetermined thickness smaller than the thickness of said insulating film is embedded in the hole formed in said insulating film, and a conductive film to be said electrode structure is formed thereon.

5. A semiconductor device having a plurality of phase change devices rewritably storing data, comprising:
an insulating film deposited on a semiconductor substrate;
a silicon nitride film formed on the sidewall surface of a hole formed at each of bit areas separated from each other in said insulating film; and
a chalcogenide film formed by embedding chalcogenide-based phase change material inside said silicon nitride film in the hole; and
an electrode structure for supplying a current to each said phase change device made of said chalcogenide film in said bit area.

6. A method of manufacturing a semiconductor device having a plurality of phase change devices rewritably storing data, comprising the steps of:
depositing an insulating film on a semiconductor substrate using a silicon nitride film;
forming a chalcogenide film by forming a hole at each of bit areas separated from each other in said insulating film and by embedding a chalcogenide-based phase change material in the hole; and
forming an electrode structure for supplying a current to each said phase change device made of said chalcogenide film in said bit areas.

7. A method of manufacturing a semiconductor device according to claim 6, wherein said chalcogenide film with a predetermined thickness smaller than the thickness of said insulating film is embedded in the hole formed in said insulating film in the step in which said chalcogenide film is formed, and a conductive film to be said electrode structure is formed on said chalcogenide film in the hole in the step in which said electrode structure is formed.

8. A method of manufacturing a semiconductor device having a plurality of phase change devices rewritably storing data, comprising the steps of:
depositing an insulating film on a semiconductor substrate using a silicon oxide film;
forming a hole at each of bit areas separated from each other in said insulating film and forming a silicon nitride film on the sidewall surface of the hole;
forming a chalcogenide film by embedding a chalcogenide-based phase change material inside said silicon nitride film in the hole; and

9. A semiconductor device according to claim 2, wherein said chalcogenide film having a predetermined thickness smaller than the thickness of said insulating film is embedded in the hole formed in said insulating film, and a conductive film to be said electrode structure is formed thereon.

10. A semiconductor device according to claim 3, wherein said chalcogenide film having a predetermined thickness smaller than the thickness of said insulating film is embedded in the hole formed in said insulating film, and a conductive film to be said electrode structure is formed thereon.
